(19) United States
(12) Patent Application Publication
(10) Pub. No.: US 2011/0175162 A1
(43) Pub. Date: Jul. 21, 2011

(54) SEMICONDUCTOR MEMORY DEVICE AND METHOD FOR FABRICATING THE SAME

(76) Inventor: Joong Sik KIM, Yongin-si (KR)

(21) Appl. No.: 13/009,182

(22) Filed: Jan. 19, 2011

(30) Foreign Application Priority Data
Jan. 19, 2010 (KR) 10-2010-0004818

(51) Int. Cl. H01L 29/78; H01L 21/475

(52) U.S. Cl. 257/330; 438/270; 257/E21.488; 257/E29.262

(57) ABSTRACT

A method for fabricating a semiconductor memory device includes: forming a trench in a substrate; forming a gate insulation layer along the trench, wherein the gate insulation layer is thicker at an upper region of the trench than at a lower region thereof; forming a gate pattern on the gate insulation layer to fill the trench; forming a first active region over a first region of the gate pattern to overlap the gate pattern at the thicker region of the gate insulation layer; and forming a second active region formed over a second region of the gate pattern and spaced apart from the first active region by a floating body formed therebetween, wherein the second region is vertically lower than the first region.

### CROSS-REFERENCE(S) TO RELATED APPLICATIONS

The present application claims priority of Korean Patent Application No. 10-2010-0004818, filed on Jan. 19, 2010, which is incorporated herein by reference in its entirety.

### BACKGROUND OF THE INVENTION

Exemplary embodiments of the present invention relate to a semiconductor device and a method for fabricating the same, and more particularly, to a floating body cell and a method for fabricating the same.

As the integration degree of semiconductor devices has been getting higher, it is difficult to fabricate a DRAM with a unit memory cell configured with one transistor and one capacitor and ensure a sufficient data retention time and prevent a short channel effect. Fabrication of a capacitor having a sufficient capacitance while minimizing a dielectric leakage in a small area has been difficult.

In particular, the fabrication of a capacitor which can meet a capacitance required for the operation of the DRAM and ensure the reliability of the DRAM is reaching limits. To overcome such limits, a memory using a floating body effect of a transistor has been used.

A memory with a floating body cell using a floating body effect writes or reads data by storing charges in a floating body and changing a threshold voltage of a transistor.

More specifically, in a memory using a floating body cell, when a high positive voltage is applied to a drain to generate hot carriers, electron hole pairs are generated by impact ionization due to the hot carriers. Electrons in the electron-hole pairs are discharged to the drain by the high voltage applied to the drain, whereas holes are accumulated in a silicon substrate. Here, due to the holes accumulated in a silicon substrate, a threshold voltage (Vt) of a transistor is reduced and a large amount of current flows when a voltage is applied. Hence, a transistor acts as a memory. For example, in such a floating body memory, a state “0” is a state in which a threshold voltage is high because holes are not accumulated, and a state “1” is a state in which a threshold voltage is low because holes are accumulated.

In the floating body memory, an erase operation is performed by discharging the charged holes by applying a forward bias to a PN junction between a source and a silicon. Since the floating body memory has no capacitor, a capacitor fabrication process and an area for a capacitor are unnecessary. Therefore, compared to a typical DRAM, the floating body memory reduces the number of manufacturing processes due to avoidance of capacitor fabrication and increases the memory density.

### SUMMARY OF THE INVENTION

An embodiment of the present invention is directed to a memory using a floating body cell, which can increase a data retention time by reducing a GIDL current, and a method for fabricating the same.

In accordance with an embodiment of the present invention, a method for fabricating a semiconductor memory device includes: forming a trench in a substrate; forming a gate insulation layer along the trench, wherein the gate insulation layer is thicker at an upper region of the trench than at a lower region thereof; forming a gate pattern on the gate insulation layer to fill the trench; forming a first active region on an upper region of the gate pattern, so that the first active region is overlapped with the thick region of the gate insulation layer; and forming a second active region formed over a second region of the gate pattern and spaced apart from the first active region by a floating body formed therebetween, wherein the second region is vertically lower than the first region.

In accordance with another embodiment of the present invention, a semiconductor memory device includes: an insulation layer disposed along a trench, wherein an upper portion of the insulation layer is thicker; a gate pattern disposed on the insulation layer; a first active region disposed over a first region of the gate pattern to overlap the gate pattern at the thicker region of the gate insulation layer; and a second active region disposed over a second region of the gate pattern and spaced apart from the first active region by a floating body disposed therebetween.

### BRIEF DESCRIPTION OF THE DRAWINGS

FIG. 1 illustrates a state in which an isolation layer is formed in a bulk silicon substrate doped with a first conductivity type.

FIG. 2 illustrates a state in which a trench is formed in the silicon substrate and the isolation layer.

FIG. 3 illustrates a state in which impurities are implanted into the bottom of the trench.

FIG. 4A illustrates a state in which halogen impurities are implanted into the upper portion of the trench at a tilt angle.

FIG. 4B illustrates the tilt angle at which the halogen impurities are implanted.

FIG. 5 illustrates a state in which a gate oxide layer is formed.

FIG. 6 illustrates a state in which a gate is formed.

FIG. 7 illustrates a state in which a mask for a drain pick-up is formed and impurities are implanted thereinto.

FIG. 8 illustrates a state in which a hard mask layer is formed at sidewalls of the gate and an oxide layer is removed from an upper portion of the silicon substrate.

FIG. 9 illustrates a floating body cell in accordance with an exemplary embodiment of the invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

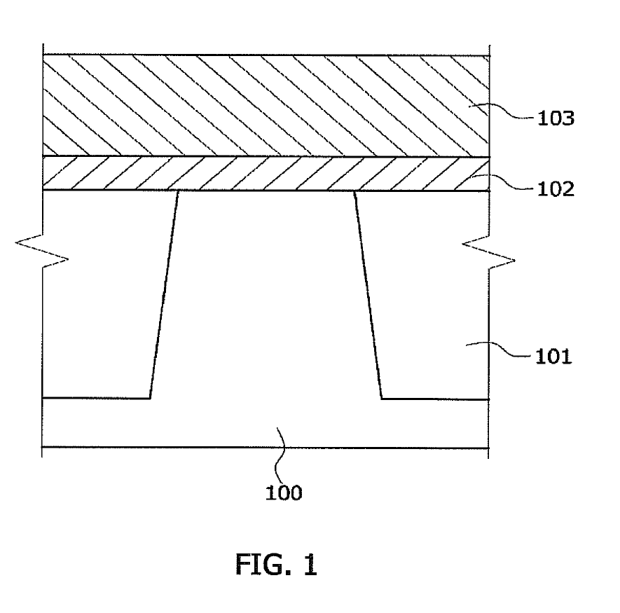

A method for fabricating a semiconductor memory device in accordance with an embodiment of the present invention will be described with reference to FIGS. 1 to 9. Referring to FIG. 1, an active region is isolated by forming an isolation layer 101 in a semiconductor substrate 100, where the semiconductor substrate 100 may be doped with a first conductivity type before the formation of the isolation layer 101. An insulation layer 102 and a hard mask layer 103 are formed on the active region and the isolation layer 101. When the first conductivity type is n type, Group V elements such as Sb, As, and P may be used as a donor for doping the substrate 100 with the first conductivity type. When the first conductivity type is p type, Group III elements such as Ga, Al and B may be used as an acceptor for doping the substrate 100 with the first conductivity. The insulation layer 102 may include a silicon oxide layer or a silicon nitride layer. The hard mask layer 103 may be at least one selected from the group consisting of a silicon-rich nitride (SRN), a TEOS layer, a silicon oxide layer, a silicon nitride layer, a SiON layer, and an amorphous carbon layer.

The memory using the floating body cell according to an example is implemented on a wafer having a Silicon On Insulator (SOI) structure. The silicon substrate having the SOI structure is formed using a Silicon On Sapphire (SOS) method of forming an epitaxial layer on a sapphire layer or a Separation by Implanted Oxygen (SIMOX) method of implanting oxygen ions into a silicon substrate and performing an annealing process to form a buried oxide layer in a bulk silicon substrate. Alternatively, the silicon substrate having the SOI structure may be formed using a wafer bonding technique. Specifically, when two sheets of silicon are attached together and thermally oxidized, an oxide layer is formed around the interface therebetween. Then, the surface of one wafer is etched and polished by a chemical mechanical polishing (CMP) process or any other reasonably suitable chemical methods, thereby forming a wafer having an SOT structure. However, the wafer having the SOI structure is relatively difficult to fabricate and its fabrication cost is relatively high.

An exemplary embodiment of the present invention provides a method for fabricating a floating memory cell using a bulk silicon substrate and a memory device using a floating body cell to reduce fabrication costs and difficulties.

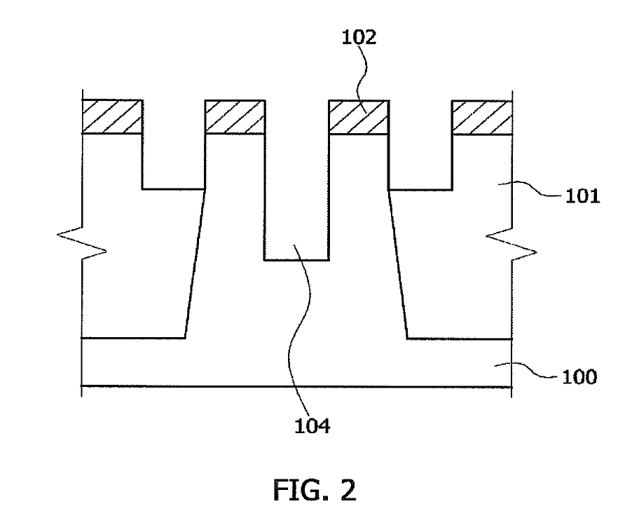

Referring to FIG. 2, a trench 104 is formed by removing a portion of the semiconductor substrate through an etching process using a mask. The trench 104 is formed by coating a pattern on the hard mask layer and etching the coated pattern. During this process, the hard mask layer is removed, and the insulation layer formed in areas for the trench is also removed.

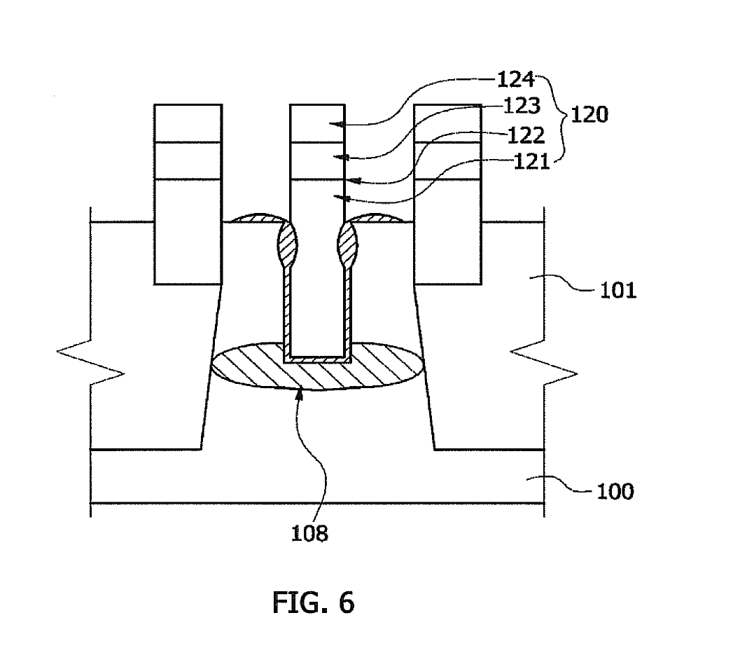

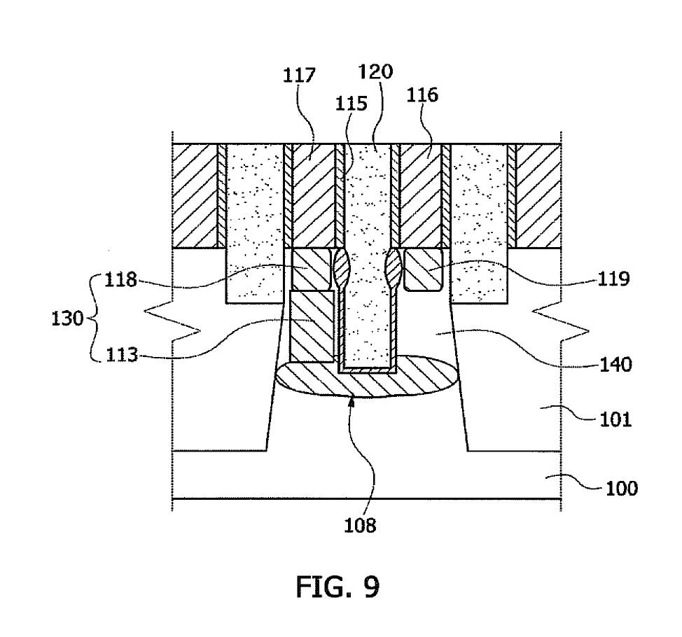

A plurality of trenches 104 may be formed in a single active area. A gate extending from the bottom of the trench 104 to above the silicon substrate is to be formed in the trench (see gate 120 in FIG. 6). The trench 104 may be formed to be deep enough to form the gate. A drain region (see first diffusion region 108 in FIG. 9) is formed in the bottom region of the trench 104, and a source region (see second diffusion region 118 in FIG. 9) is formed in the upper region of the trench. A floating body is formed between the drain region and the source region (see floating body 140 in FIG. 9). The trench 104 may be formed to be deep enough to accumulate a sufficient amount of majority carriers in the floating body.

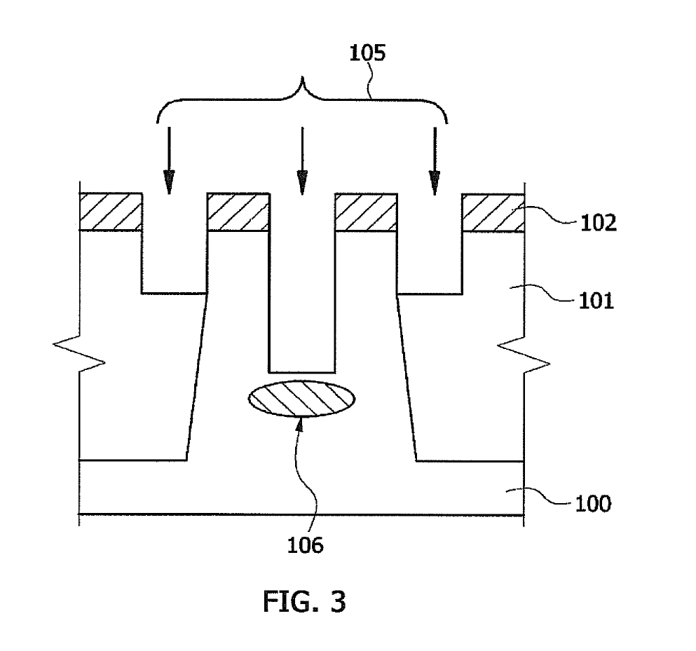

Referring to FIG. 3, an oxide layer 102 remains on regions of the silicon substrate of the active region where no trenches are to be formed. As indicated by reference numeral 105, impurities of a second conductivity type are implanted into the bottom of the trench by using the oxide layer 102 as a barrier and form the impurity implanted region 106. At this time, the implanted impurities may be acceptor ions or donor ions. The oxide layer is used as a barrier to prevent impurities from being implanted into the silicon substrate around the trench. The impurity implanted region 106 becomes a portion of a drain region. At this time, the oxide layer 102 is formed to be sufficiently thick so that impurities are implanted into only the lower portion of the trench 104, and impurities are not implanted into the other regions. If impurities are implanted into the silicon substrate 100 around the trench 104, the drain region may be formed to be excessively large. Since the oxide layer 102 serves as a barrier when the impurities are implanted, it prevents the drain region from being excessively large. If the drain region is excessively large, a region where a floating body is to be formed may be lost, where the floating body may not have a sufficient volume to accumulate majority carriers.

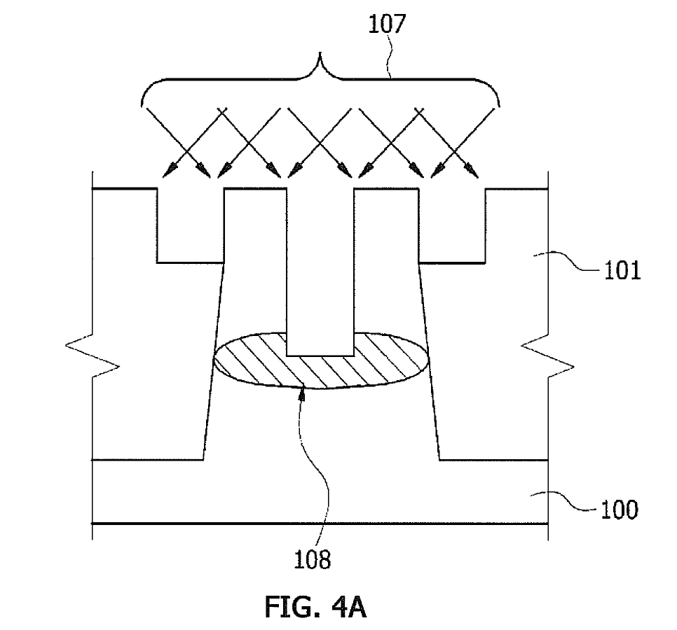

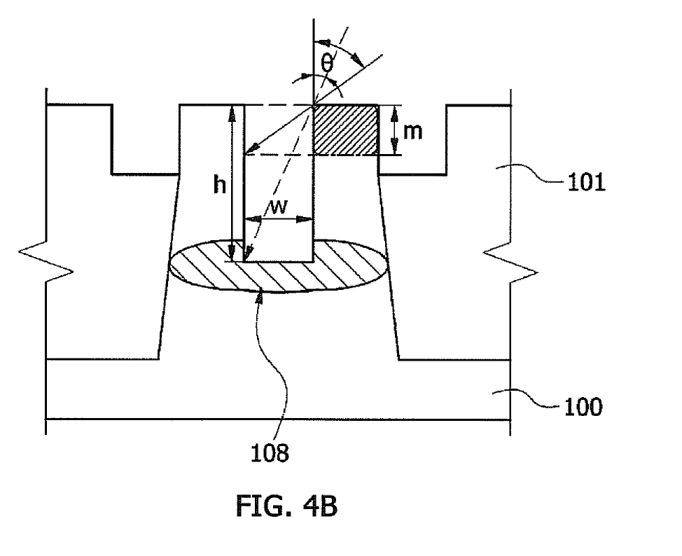

Impurities in the impurity implanted region 106 are diffused in lateral directions during a subsequent annealing process to thereby form a first diffusion region (108 in FIG. 4B). The first diffusion region 108 serves as a drain region of a floating body cell. The first diffusion region 108 diffused in lateral directions is used as a region for electrical connection to a conductive pattern which is to be formed thereon in a subsequent process. Here, according to an example, the annealing process for diffusing impurities in the impurity implanted region 106 may not be performed immediately after the impurities of the second conductivity type are implanted into the bottom of the trench. In addition, the first diffusion region 108 need not be formed through an independent annealing process and may be formed by using heat generated during other manufacturing processes. The oxide layer 102 remaining on the silicon substrate is removed during a cleaning process to remove impurities existing within the trench before forming a gate oxide layer.

Referring to FIG. 4A, after or before performing the above-discussed subsequent annealing process, halogen impurities are tilt implanted into the upper portion of the silicon substrate at a designated angle as indicated by reference numeral 107. Then, an oxide layer is formed. The oxide layer formed within the trench 104 in this step serves as a gate insulation layer. Halogen impurities implanted in this step may be Fluorine (F), Chlorine (Cl), hydrogen chloride (HCl), or trichloroethylene (TCE). According to an example, F may be used because it has little influence on device characteristics. In addition, the impurities implanted in the previous processes may be diffused together with the halogen impurities during the subsequent annealing process to form the first diffusion region 108 in the bottom of the trench.

A tilt angle at which the halogen impurities are implanted is described with reference to FIG. 4B. In FIG. 4B, W denotes the width of the trench, h denotes the height of the trench 104, m denotes the depth of the source to be formed by diffusion, and Θ denotes the angle between the vertical line and the angle at which the halogen impurities are implanted. In this case, the implantation angle is tan−1(W/m) and tan−1(W/m)≦Θ.

In this step, when the halogen impurities are implanted at a designated angle, the halogen impurities are implanted into the upper trench region.

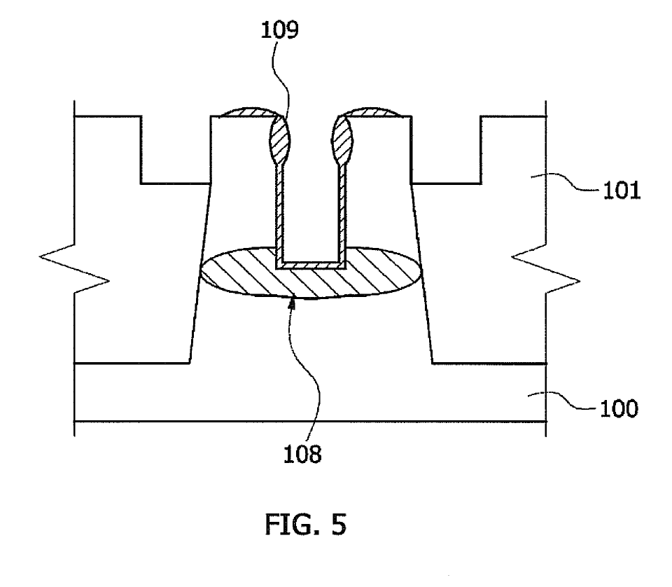

Referring to FIG. 5, an oxide layer 109 is formed along the trench region. Due to the halogen impurities implanted, the upper portion of the gate oxide layer formed within the trench is formed to be thicker than the lower portion thereof. For example, the maximum thickness of the oxide layer in the region where the halogen impurities are implanted is about 100 Å, whereas the thickness of the oxide layer in the region where the halogen impurities are not implanted is about 50 Å. More specifically, referring to FIG. 9, the thickness of the gate oxide layer formed in the overlapped region of a gate pattern 120 and a second diffusion region 119 is larger than the thickness of the gate oxide layer formed in the overlapped region of the gate pattern 120 and the floating body 140 or the overlapped region of the gate 120 and the first diffusion region 108. Therefore, the oxide layer can be formed to be thicker in the overlapped region of the gate pattern and the source region by adjusting the tilt angle when the halogen impurities are implanted.

If the thickness of the gate oxide layer formed in the overlapped region of the gate pattern and the source region of the floating body cell is larger than the thickness of the gate oxide layer formed in the overlapped region of the gate and the floating body or the overlapped region of the gate and the drain region, a gate induced drain leakage (GIDL) current may be significantly reduced. The GIDL refers to a phenomenon that a large amount of current flows from the drain region to the bulk when a reverse bias is applied to a gate of an n-channel metal oxide semiconductor field effect transistor (MOSFET) and a high forward bias is applied to the drain region, where a high electric field is generated at the gate oxide layer formed in the overlapped region of the drain region and the gate pattern and a large amount of a current flows from the drain region to the bulk due to a tunneling effect.

The GIDL phenomenon also occurs in the floating body cell. However, due to operation characteristics of the floating body cell, the GIDL phenomenon occurs, for example, only in the overlapped region of the source region and the gate pattern.

In the case of the n-channel floating body cell, a current due to a transfer of holes may flow into the body and may shorten data retention. When data corresponding to logic state 1 is written in the n-channel floating body cell, holes are accumulated in the body. Thus, no special problem is caused even though holes are introduced by the GIDL current. However, when data corresponding to logic state 0 is written in the n-channel floating body cell, holes are introduced in a state where holes are not to be accumulated in the body. Here, effective data retention time may be reduced due to the GIDL current.

In the case of the floating body cell, the GIDL current is proportional to the magnitude of an electric field applied to the oxide layer of the gate pattern that overlap the source region. When the thickness of the oxide layer is increased, the magnitude of the electric field applied to either ends thereof is reduced. Thus, the GIDL current may be reduced and the data of the floating body cell may be retained reliably.

In the floating body cell in accordance with the embodiment of the present invention, the thickness (Tox) of the gate oxide layer in the overlapped region of the gate pattern and the source region may be two times larger than the gate oxide layer in the other region. Therefore, the magnitude of the GIDL current of the floating body cell may be reduced and the data retention time may be increased.

Referring to FIG. 6, the trench 104 is filled and a gate pattern 120 is formed to be higher than the silicon substrate 100. The gate pattern may be formed by stacking a polysilicon layer 121, a metal layer 123, and a hard mask layer 124. The metal layer may be aluminum (Al), copper (Cu), or tungsten (W). In a case in which the gate 120 is formed using a polysilicon layer and a metal layer, a glue-metal layer 122 such as titanium (Ti) or titanium nitride (TiN) may be formed between the polysilicon layer and the metal layer in order to reduce a contact resistance between the two materials and firmly attach the two materials to each other. According to another example, instead of using the gate in which the polysilicon layer and the metal layer are stacked, a gate electrode layer may be formed of a single material by, for example, using cobalt silicide. After forming the gate pattern, an oxide layer (not shown) may be formed at sidewalls of the gate through a selective oxidation process in order to protect the gate pattern in a subsequent etching process.

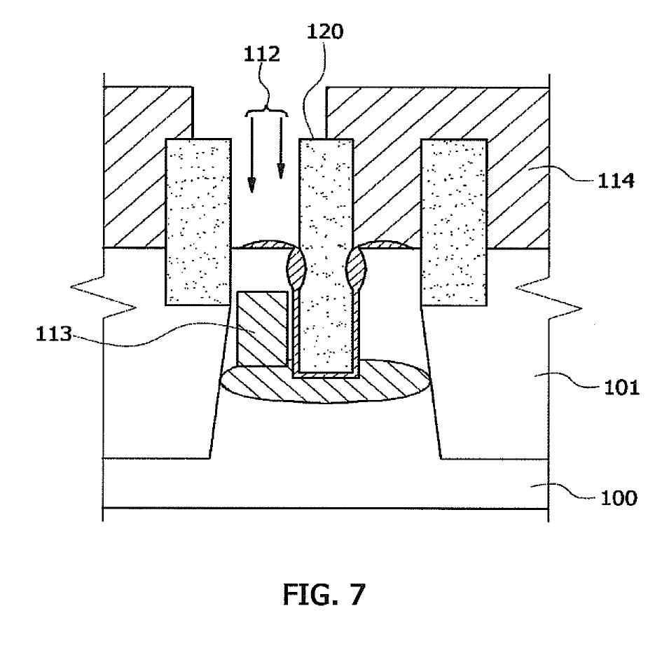

Referring to FIG. 7, a mask pattern 114 is formed in order to form a drain pick-up region (113 in FIG. 9) for electrical connection to the first diffusion region 108 formed at the bottom of the trench. Since the impurities are prevented from being implanted into a region where the floating body is to be formed (see the floating body 140 in FIG. 9), an opening of the photomask mask 114 is to be formed in an area overlying the drain pick-up region which is electrically connected to the drain region disposed at the bottom of the trench. Impurities 112 of the second conductivity type are implanted using the mask pattern 114.

The impurities of the second conductivity type are implanted with enough energy to electrically connect the implanted region to the first diffusion region 108. The impurities implanted through this process form the drain pick-up region 113 which is electrically connected to the first diffusion region 108.

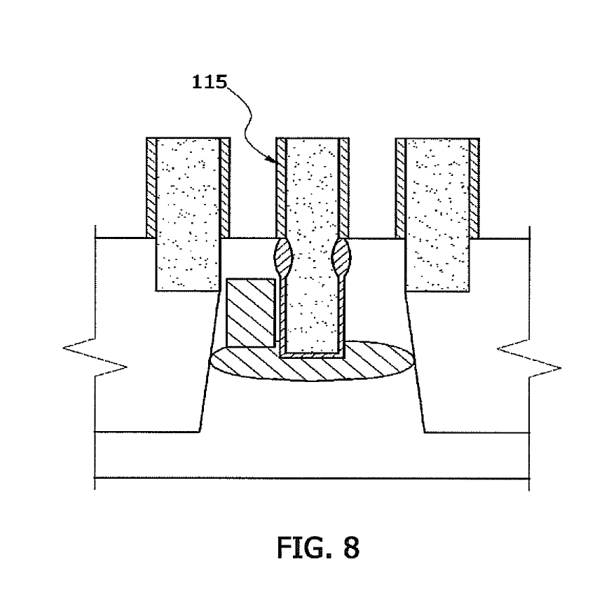

Referring to FIG. 8, a hard mask layer 115 is formed at sidewalls of the gate pattern, and the oxide layer remaining on the silicon substrate of the active region is etched away. At this time, the hard mask layer 115 serves to protect the gate pattern during a subsequent etching process and also serves to insulate the adjacent gates.

Referring to FIG. 9, a polysilicon pattern 117 is formed by filling a gap between the adjacent gate patterns with a polysilicon doped with the second conductivity type and operates as a contact plug. Second diffusion regions 118 and 119 are formed by diffusing impurities of the second conductivity type doped into the polysilicon pattern 117 buried between the gate patterns in a subsequent process.

After a chemical mechanical polishing (CMP) process, the doped polysilicon layer 117 of the second conductivity type formed on the drain pick-up region becomes a drain contact. The hard mask layer 115 stacked on the gate 120 (separate layers of the gate 120 are not individually shown) protects the gate during the CMP process.

In addition, the drain pick-up region 113 and the second diffusion region 118 formed by diffusing the impurities of the second conductivity type from the polysilicon pattern 117 buried between the gates on the drain pick-up region constitute a drain pick-up unit 130. Accordingly, the drain contact 117 electrically contacts the drain region, that is, the first diffusion region 108, through the drain pick-up unit 130. The polysilicon pattern buried between the gates in the region where the drain pick-up unit 130 that includes a drain pick-up region such as the drain pick-up region 113 is not formed becomes a source contact 116 and the source contact 116 is a contact plug. The second diffusion region 119 diffused therefrom through the subsequent annealing becomes a source region.

In addition, the silicon substrate region 140 of the first conductivity type disposed between the source region 119 and the drain region 108 becomes a floating body 140 which accumulates holes or electrons according to the doped conductivity type.

The floating body cell in accordance with the exemplary embodiment of the present invention will be described with reference to FIG. 9. The floating body cell in accordance with the exemplary embodiment of the present invention includes: a trench in which a portion of the silicon substrate 100 of a first conductivity type is removed; a first diffusion region 108 of a second conductivity type, which is adjacent to the bottom of the trench and extends in lateral directions; second diffusion regions 118 and 119 of a second conductivity type, which are adjacent to the upper portion of the trench; a gate pattern 120 extending upward from the bottom of the trench; and an oxide layer 115 disposed between the trench and the gate pattern, wherein the thickness of the overlapped region of the gate and the second diffusion region is larger than the thickness of the overlapped region of the gate pattern and the drain region and the overlapped region of the gate pattern and a channel (a floating body region).

The first diffusion region acts as a drain region, and one of the second diffusion regions acts as a source region. The silicon substrate region disposed between the drain region and the source region becomes the floating body 140. The gate pattern extends from the trench to a position higher than the surface of the silicon substrate. The gate pattern may be formed of cobalt silicide. Also, the gate pattern may be formed by stacking a polysilicon layer and a metal layer such as Al, Cu, or W. At this time, a glue-metal such as Ti or TiN may be used for reducing a contact resistance between the polysilicon layer and the metal layer and firmly attach the polysilicon layer and the metal layer to each other.

The oxide layer of the gate pattern formed along the trench is thicker in the overlapped region of the gate and the source region than in other regions. Therefore, the floating body cell in accordance with the embodiment of the present invention may reduce the GIDL current and thus increase the data retention time.

The drain pick-up region 113 is electrically connected to the drain contact 117 through the second diffusion region 118. The second diffusion region 118 is formed by the diffusion of the impurities of the second conductivity type in the polysilicon layer 117 of the second conductivity type. Therefore, the drain region 108 is electrically connected to the drain contact 117 through the drain pick-up unit 130 including the drain pick-up region 113 and the second diffusion region 118. Thus, the drain contact 117 and the source contact 116 are electrically connected to the drain region and the source region of the floating body cell, respectively.

In accordance with the embodiment of the present invention, the memory cell having no capacitor is implemented, and thus, high-integration memory may be implemented.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor memory device, the method comprising:
forming a trench in a substrate;
forming a gate insulation layer along the trench, wherein the gate insulation layer is thicker at an upper region of the trench than at a lower region thereof;
forming a gate pattern on the gate insulation layer to fill the trench;
forming a first active region over a first region of the gate pattern to overlap the gate pattern at the thicker region of the gate insulation layer; and
forming a second active region formed over a second region of the gate pattern and spaced apart from the first active region by a floating body formed therebetween, wherein the second region is vertically lower than the first region.

2. The method of claim 1, wherein the forming of the gate insulation layer comprises:
implanting impurities in the first region of the trench at a first tilt angle; and
forming the gate insulation layer on the trench.

3. The method of claim 2, wherein the impurities comprise halogen impurities.

4. The method of claim 3, wherein the halogen impurities comprise fluorine (F).

5. The method of claim 1, wherein the gate pattern fills the trench and is formed to rise higher than the substrate.

6. The method of claim 1, further comprising:
forming an insulation layer on the gate pattern formed on the trench; and
forming a first contact plug contacting a side of the gate pattern,
wherein the first active region is formed by diffusing the impurities contained in the first contact plug toward the substrate.

7. The method of claim 1, wherein the second active region is formed to overlap opposite sides of a lower end of the gate pattern.

8. The method of claim 6, further comprising:
forming a conductive pick-up region electrically connected to the second active region formed at the other side of the gate pattern;
forming a second contact plug contacting the gate pattern at the other side of the gate pattern; and
forming a third active region contacting the conductive pick-up region and the second contact plug by diffusing the impurities of the second contact plug.

9. The method of claim 8, wherein the first active region and the third active region are formed at the same manufacturing step.

10. The method of claim 1, wherein the gate pattern has a structure in which a conductive polysilicon layer and a metal layer are stacked.

11. The method of claim 2, wherein the first tilt angle (Θ) is tan−1(W/m)≦Θ, where W denotes the width of the trench, and m denotes the depth of the first active region.

12. The method of claim 1, wherein the first and second active regions form first and second drain/source electrodes, respectively.

13. The method of claim 1, further comprising forming first and second contact plugs at opposite sides of the gate pattern, forming a structure for electrically connecting the first contact plug to the second active region on a side of the gate pattern, and forming a floating body on the opposite side of the gate pattern.

14. A semiconductor memory device, comprising:
an insulation layer disposed along a trench, wherein an upper portion of the insulation layer is thicker;
a gate pattern disposed on the insulation layer;
a first active region disposed over a first region of the gate pattern to overlap the gate pattern at the thicker region of the gate insulation layer; and
a second active region disposed over a second region of the gate pattern and spaced apart from the first active region by a floating body disposed therebetween.

15. The semiconductor memory device of claim 14, wherein the gate pattern is formed to rise over the trench.

16. The semiconductor memory device of claim 14, wherein the second active region is disposed to overlap opposite sides of a lower end of the gate pattern.

17. The semiconductor memory device of claim 14, further comprising a first contact plug electrically connected to the gate pattern and the first active region at a side of the gate pattern formed in the trench.

18. The semiconductor memory device of claim 17, further comprising:
a conductive pick-up region electrically connected to the second active region disposed at the other side of the gate pattern;
a third active region electrically connected to the conductive pick-up region; and
a second contact plug contacting the third active region at the other side of the gate pattern.

19. The method of claim 14, wherein the gate pattern has a structure in which a polysilicon layer and a metal layer are stacked.

20. The method of claim 19, wherein the metal layer comprises at least one selected from tungsten (W), cobalt silicide, and nickel silicide.

21. The method of claim 14, wherein the gate pattern comprises cobalt silicide.
